(19) United States
(12) Patent Application Publication
(10) Pub. No.: US 2025/0017000 A1
(43) Pub. Date: Jan. 9, 2025

(54) SEMICONDUCTOR DEVICE STRUCTURE INCLUDING FUSE STRUCTURE EMBEDDED IN SUBSTRATE

(71) Applicant: NANYA TECHNOLOGY CORPORATION, NEW TAIPEI CITY (TW)

(72) Inventor: HSIH-YANG CHIU, TAOYUAN CITY (TW)

(21) Appl. No.: 18/217,717

(22) Filed: Jul. 3, 2023

(51) Int. Cl. H10B 20/25; H01L 23/525

(52) U.S. Cl. CPC H10B 20/25; H01L 23/5256

(57) ABSTRACT

A semiconductor device structure and a method of manufacturing the same are provided. The semiconductor device structure includes a substrate, a fuse structure, and a first word line. The fuse structure includes a fuse electrode disposed within the substrate. The first word line is electrically coupled to the fuse structure. The first word line is disposed within the substrate and spaced apart from the fuse electrode of the fuse structure. The fuse electrode has a lateral surface protruding toward the first word line.

### TECHNICAL FIELD

The present disclosure relates to a semiconductor device structure and a method of manufacturing the same, in particularly to a semiconductor device structure including a fuse structure embedded within a substrate.

### Discussion of the Background

Many integrated circuits (ICs) are made up of millions of interconnected devices, such as transistors, resistors, capacitors, and diodes, on a single chip of a semiconductor substrate. It is generally desirable that ICs operate as fast as possible, and consume as little power as possible. Semiconductor ICs often include one or more types of memory, such as complementary metal-oxide-semiconductor (CMOS) memory, antifuse memory, and efuse memory.

EFuses are usually integrated into semiconductor ICs by a semiconductor material (e.g., a polysilicon or a metallization layer) disposed on a dielectric layer (e.g., silicon oxide). A programing current is applied to blow the dielectric layer, thus changing the resistivity of the eFuse. This is referred to as “programming” the eFuse. However, such structure requires a relatively large breakdown voltage, which may adversely affect the performance of a semiconductor device. Further, conventional eFuse structures occupies a relatively large space over the substrate, reducing the densities of ICs.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device structure. The semiconductor device structure includes a substrate, a fuse structure, and a first word line. The fuse structure includes a fuse electrode disposed within the substrate. The first word line is electrically coupled to the fuse structure. The first word line is disposed within the substrate and spaced apart from the fuse electrode of the fuse structure. The fuse electrode has a lateral surface protruding toward the first word line.

Another aspect of the present disclosure provides a semiconductor device structure. The semiconductor device structure includes a substrate, a fuse structure, and a first word line. The fuse structure includes a fuse electrode disposed within the substrate. The first word line is electrically coupled to the fuse structure. A distance between the fuse electrode of the fuse structure and the first word line varies along a direction far away from the substrate.

Another aspect of the present disclosure provides a method for manufacturing a semiconductor device structure. The method includes: providing a substrate; forming a first word line and a second word line within the substrate; forming an opening extending from an upper surface of the substrate and between the first word line and the second word line; and forming an insulation layer within the opening; and forming a metallization layer over the insulation layer to define a fuse structure.

The embodiments of the present disclosure provide a semiconductor device structure. The semiconductor device structure includes a substrate, a fuse structure, a first word line, and a second word line. The first word line is electrically coupled with the fuse structure. Further, the first word line and the second word line are electrically coupled in parallel. As a result, a relatively large driving current can be generated. The fuse electrode of the fuse structure has a lateral surface protruded toward the first word line and the second word line. The semiconductor device structure can have a relatively small resistance between the fuse structure and the first word line (or the second word line). Accordingly, the fuse structure can be blown out with a smaller voltage.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

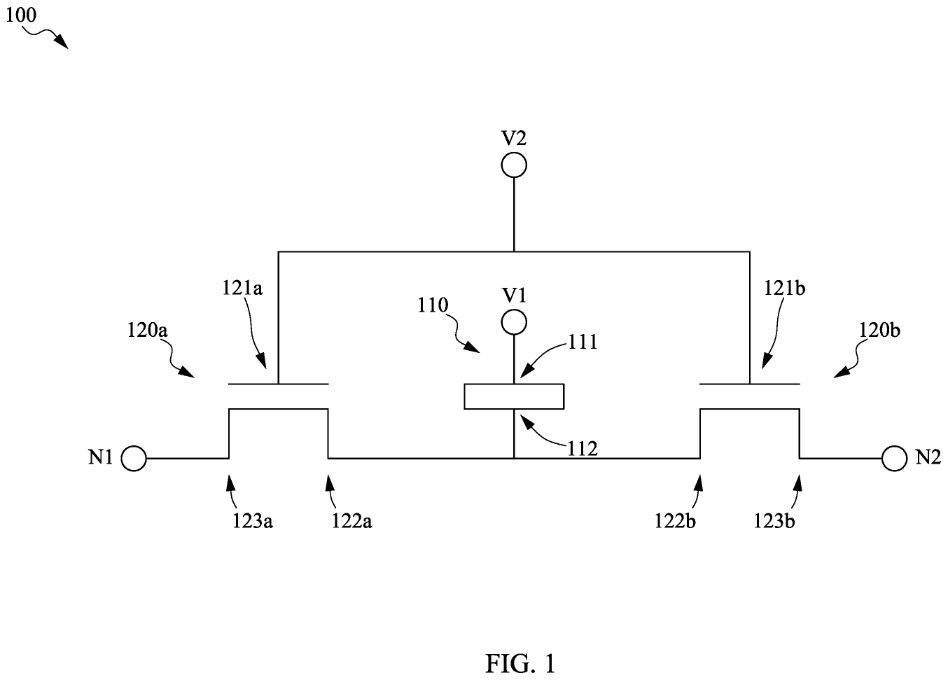

FIG. 1 is a schematic diagram of a circuit, in accordance with some embodiments of the present disclosure.

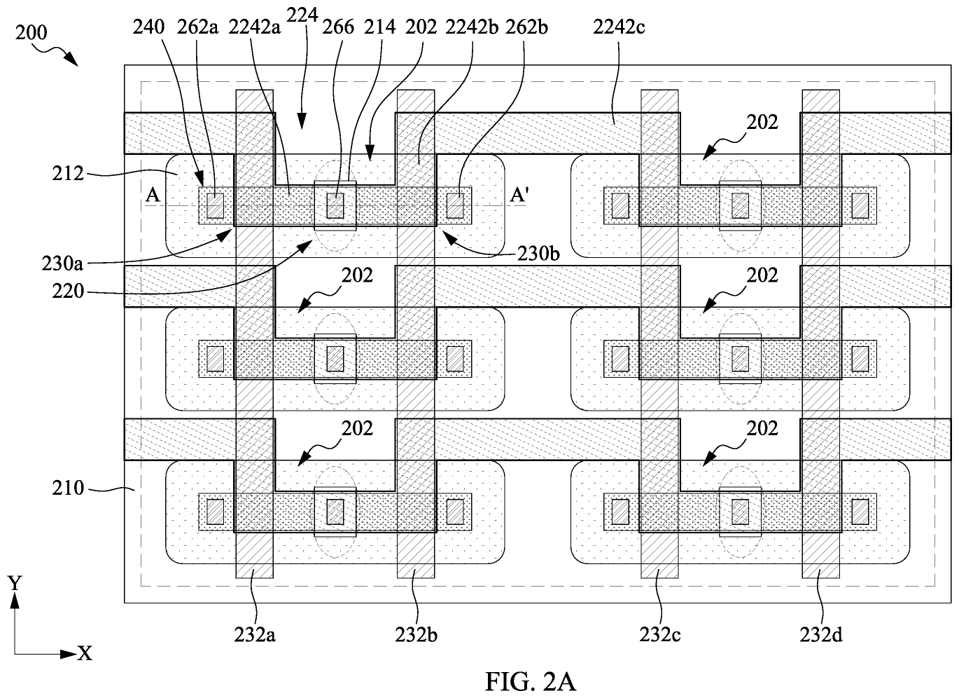

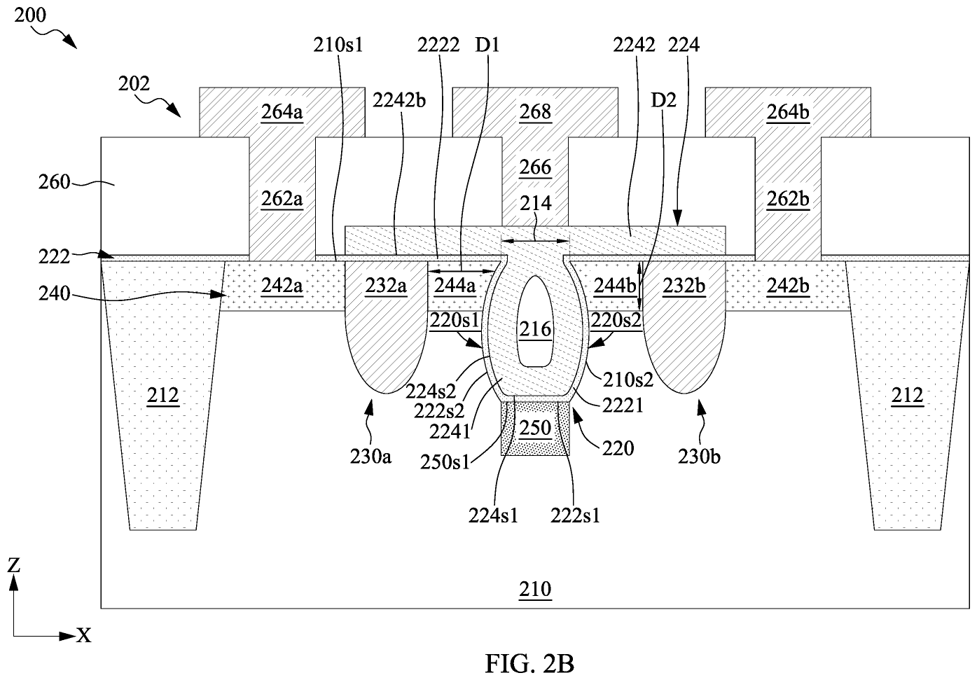

FIG. 2A is a top view of a semiconductor device structure, in accordance with some embodiments of the present disclosure.

FIG. 2B is a cross-section along line A-A′ of the semiconductor device structure as shown in FIG. 2A, in accordance with some embodiments of the present disclosure.

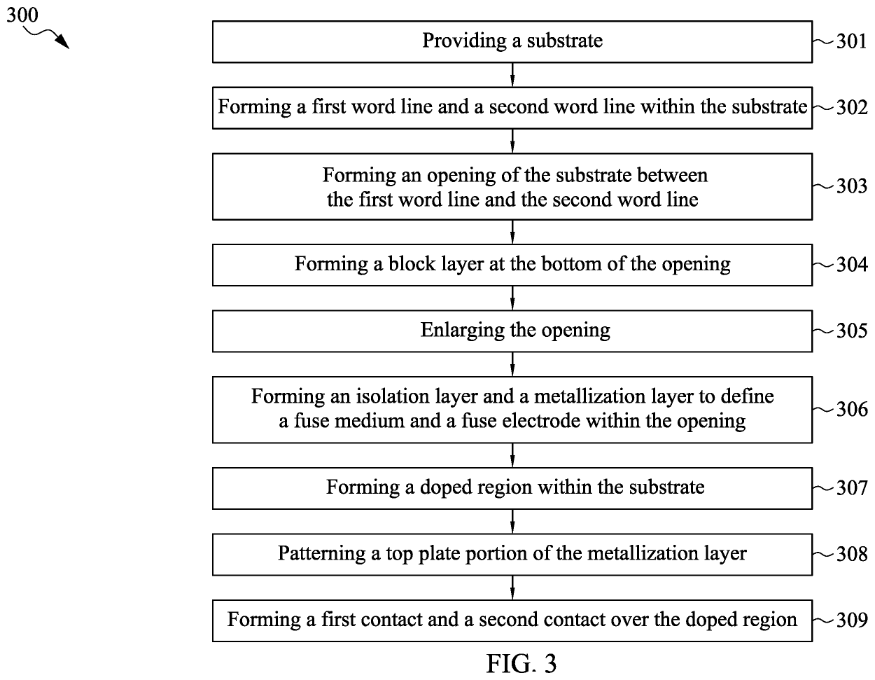

FIG. 3 is a flowchart illustrating a method of manufacturing a semiconductor device structure, in accordance with some embodiments of the present disclosure.

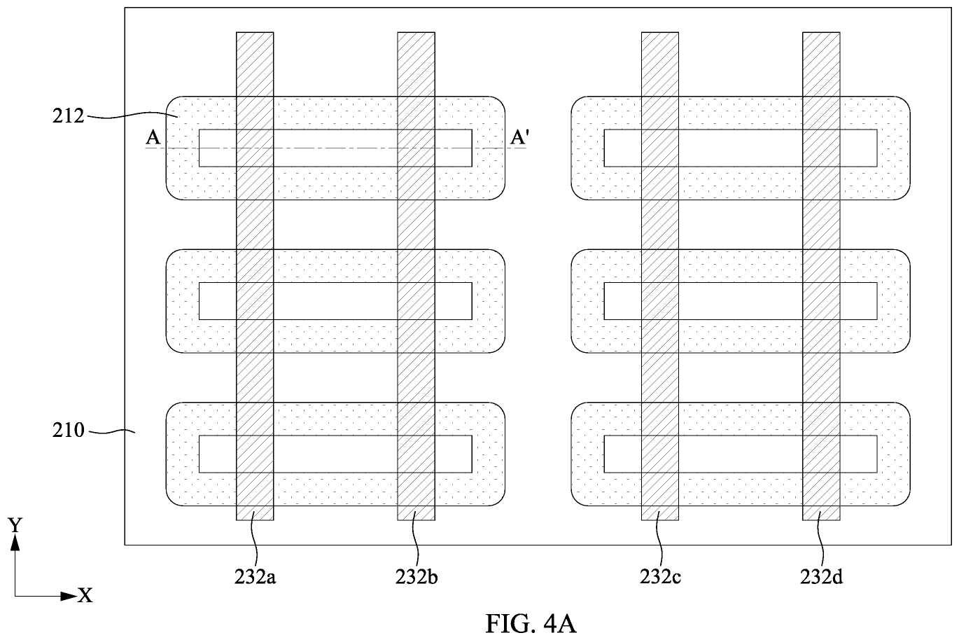

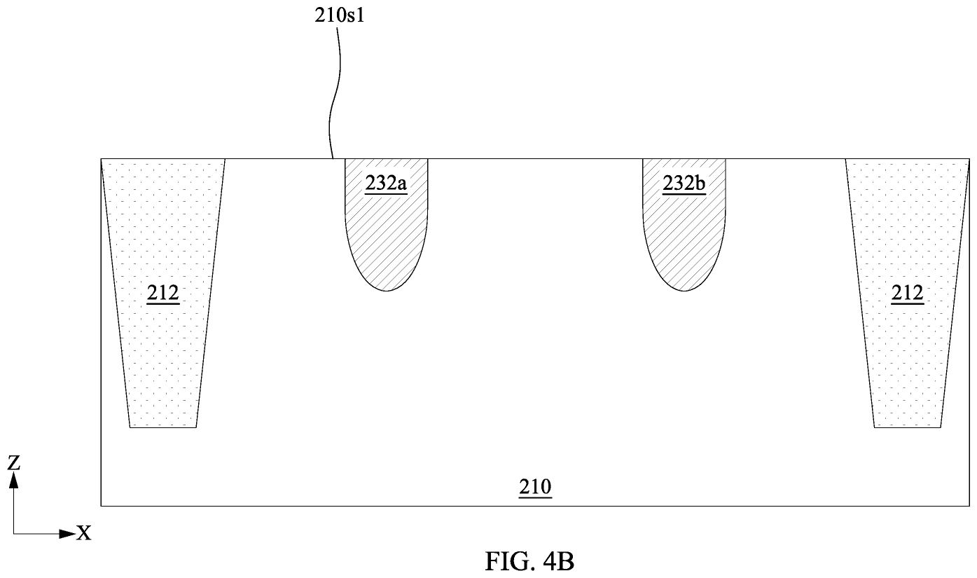

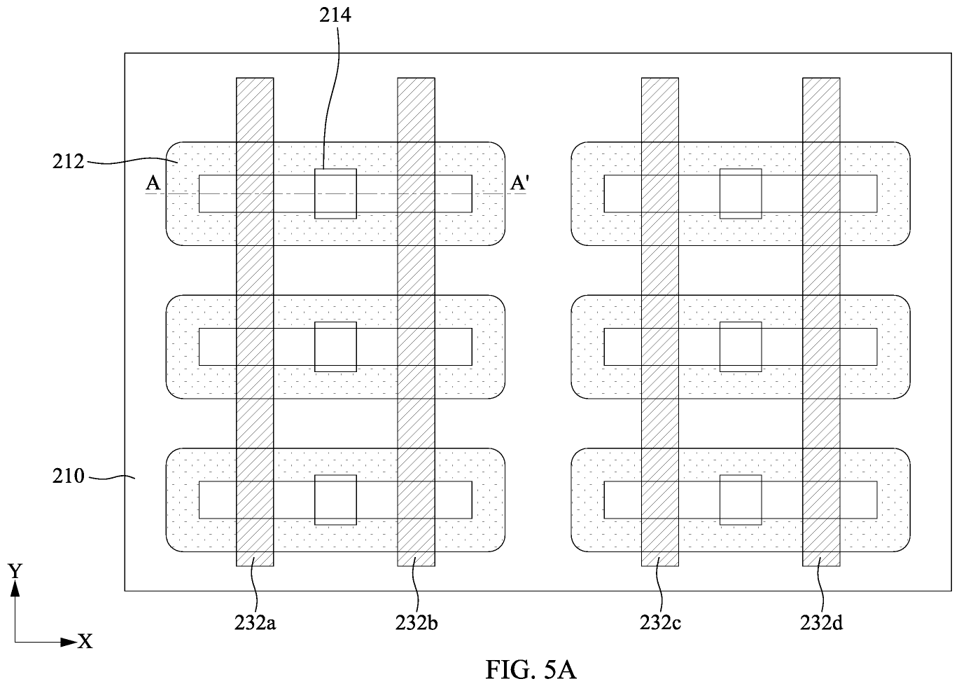

FIG. 4A and FIG. 4B illustrate one or more stages of an exemplary method for manufacturing a semiconductor device structure according to some embodiments of the present disclosure in different perspectives.

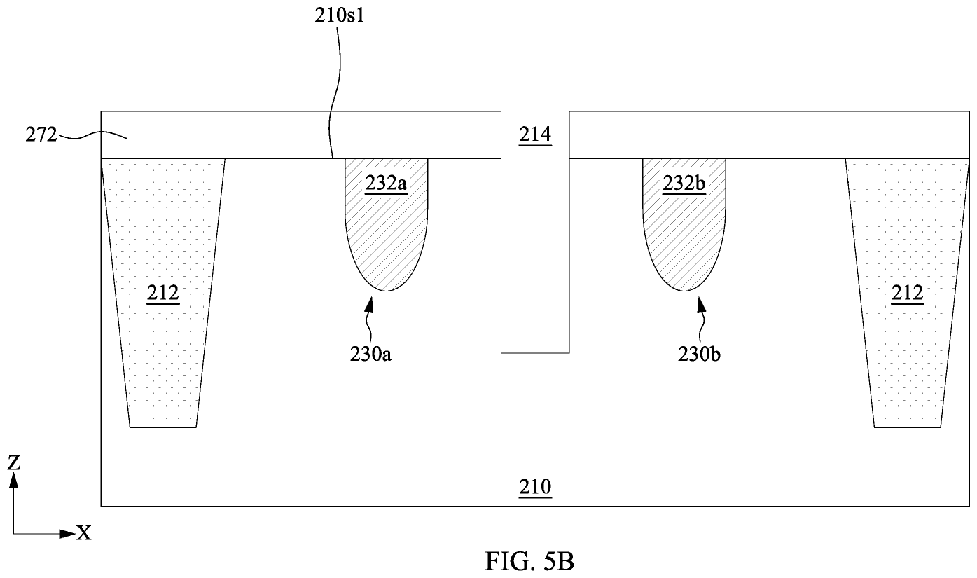

FIG. 5A and FIG. 5B illustrate one or more stages of an exemplary method for manufacturing a semiconductor device structure according to some embodiments of the present disclosure in different perspectives.

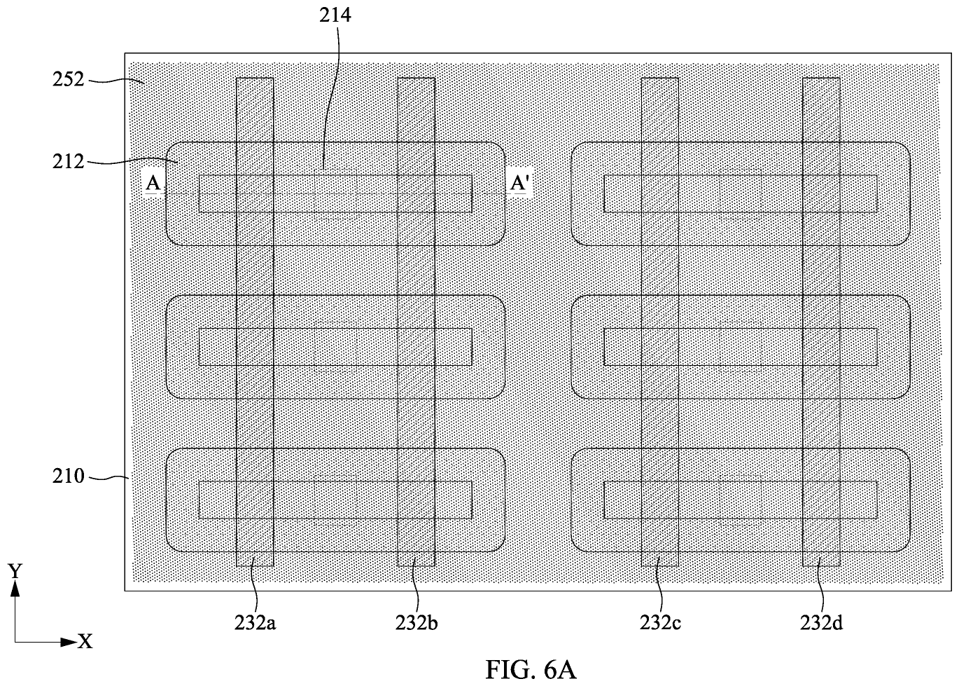

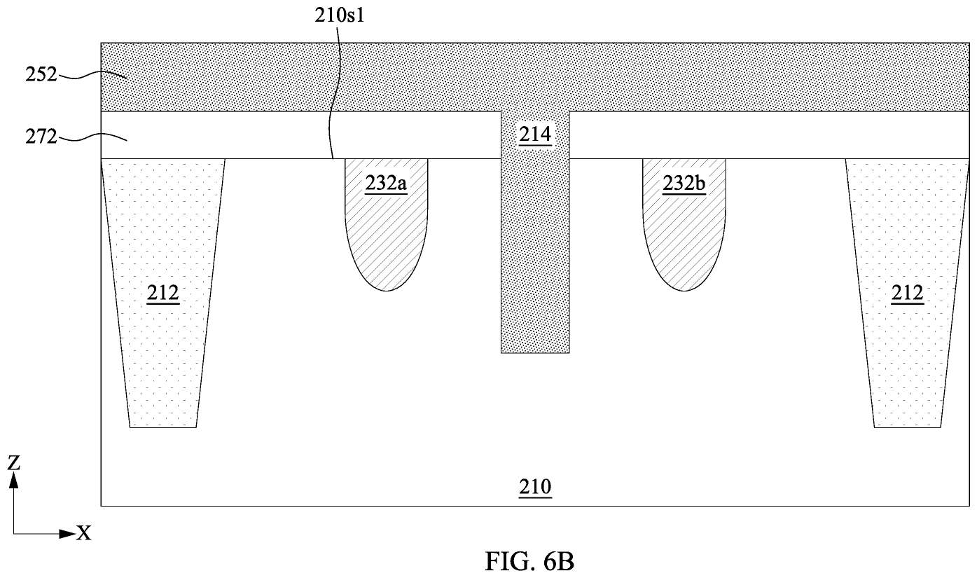

FIG. 6A and FIG. 6B illustrate one or more stages of an exemplary method for manufacturing a semiconductor device structure according to some embodiments of the present disclosure in different perspectives.

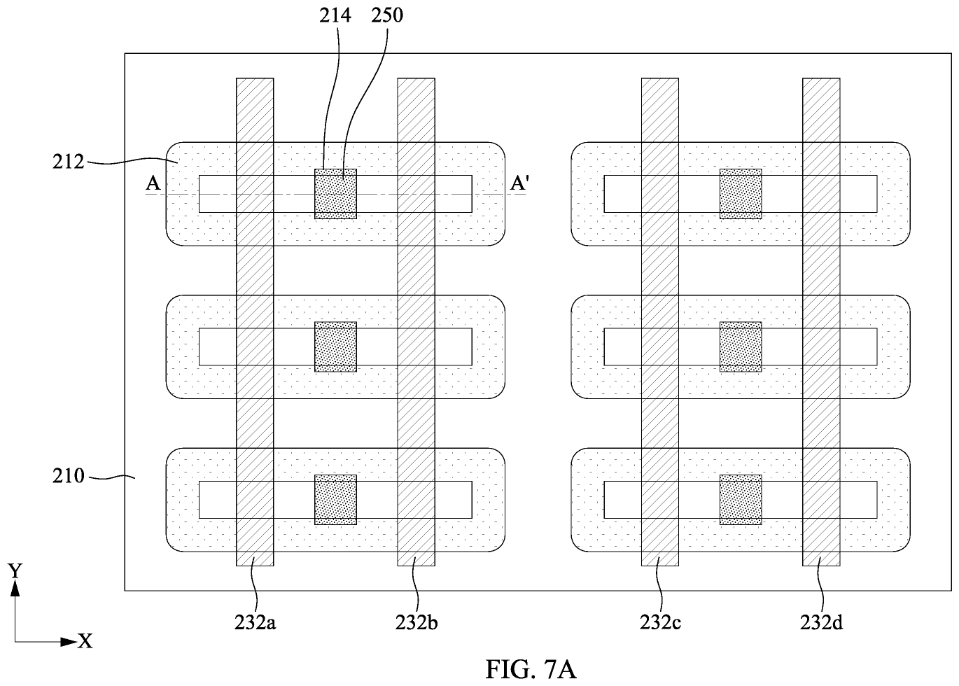

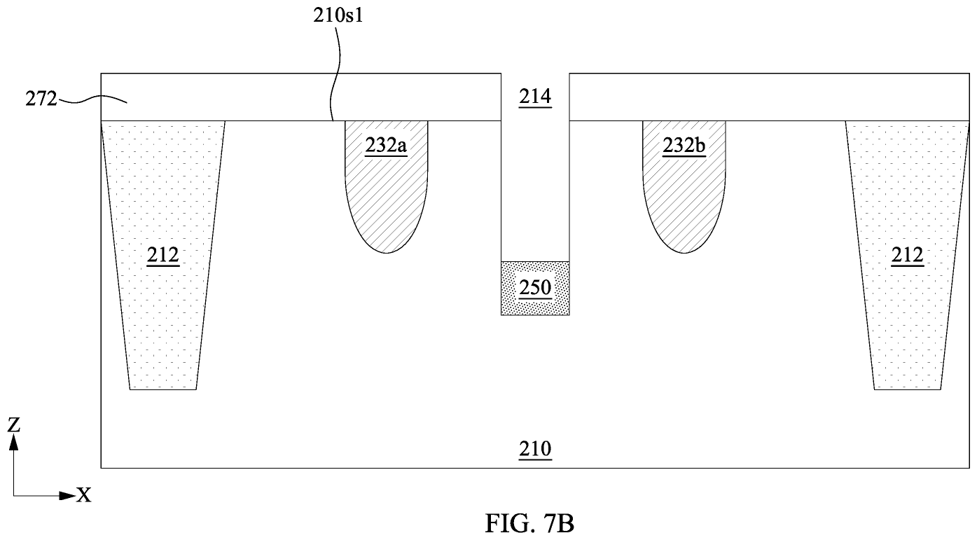

FIG. 7A and FIG. 7B illustrate one or more stages of an exemplary method for manufacturing a semiconductor device structure according to some embodiments of the present disclosure in different perspectives.

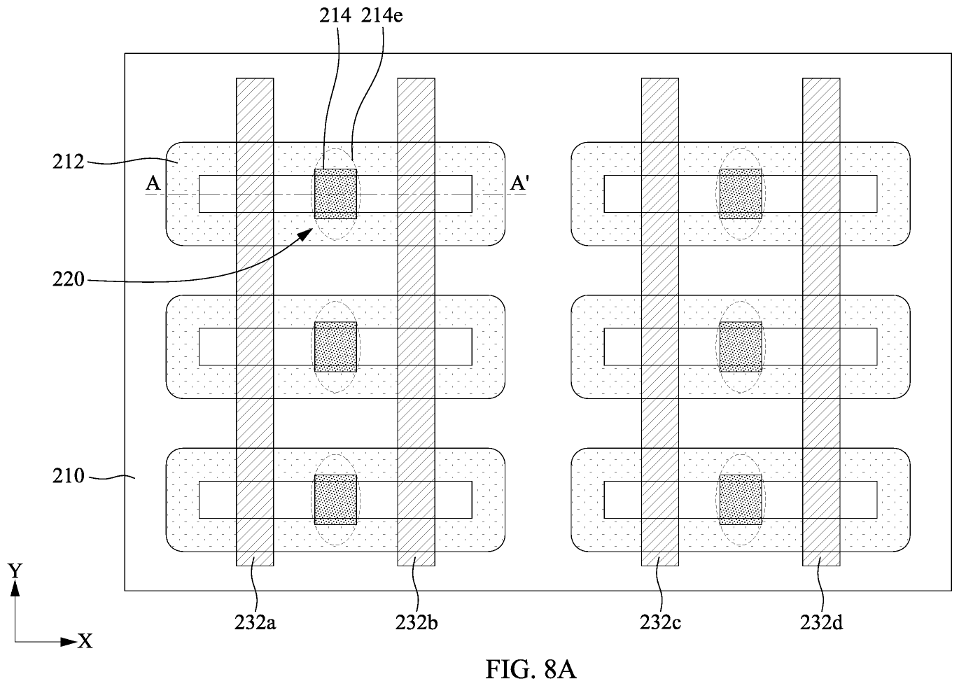

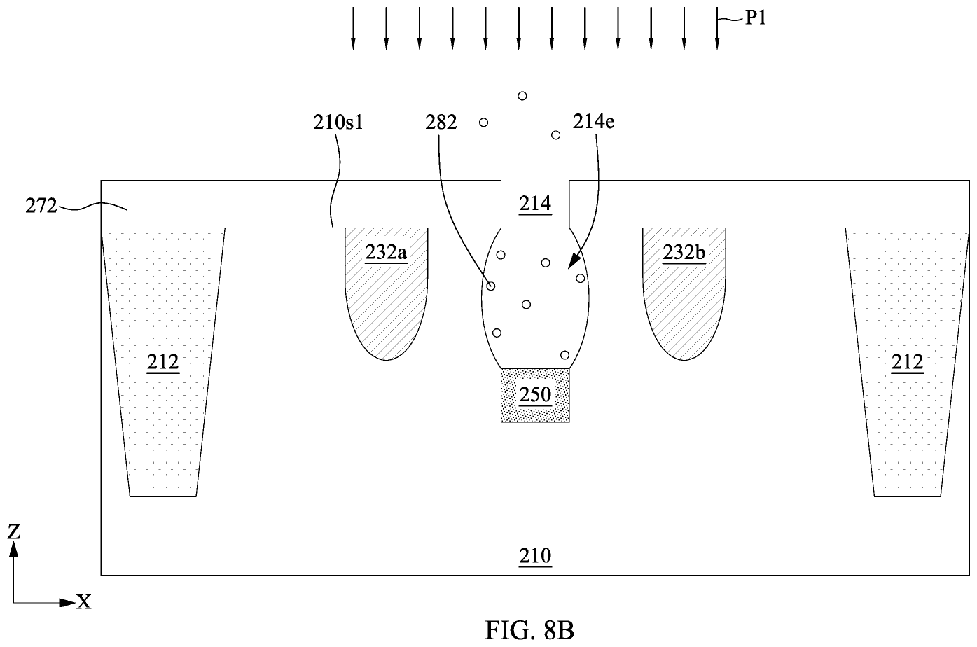

FIG. 8A and FIG. 8B illustrate one or more stages of an exemplary method for manufacturing a semiconductor device structure according to some embodiments of the present disclosure in different perspectives.

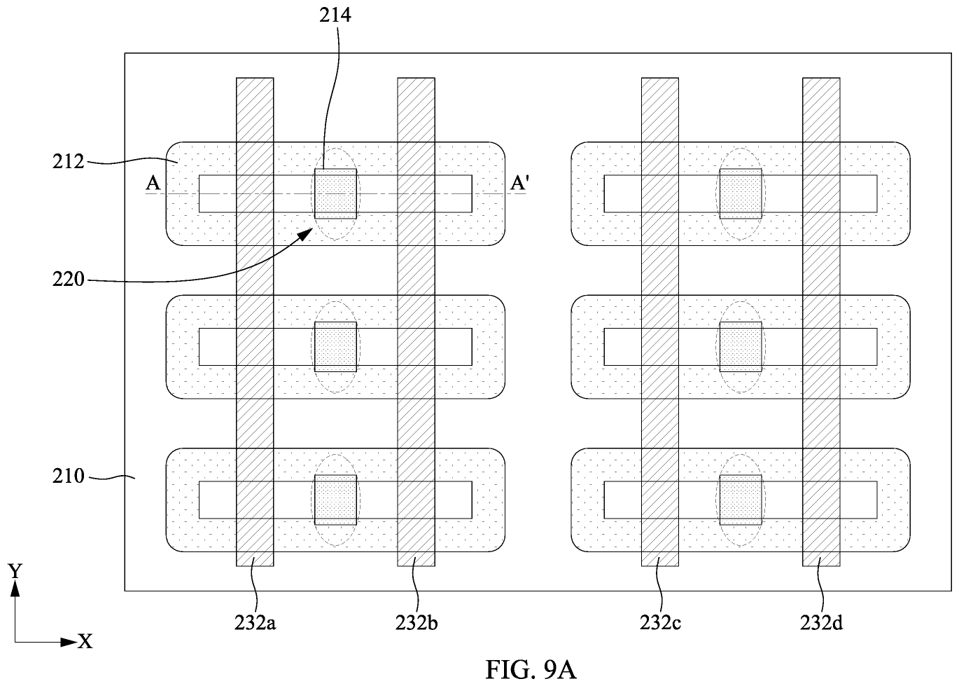

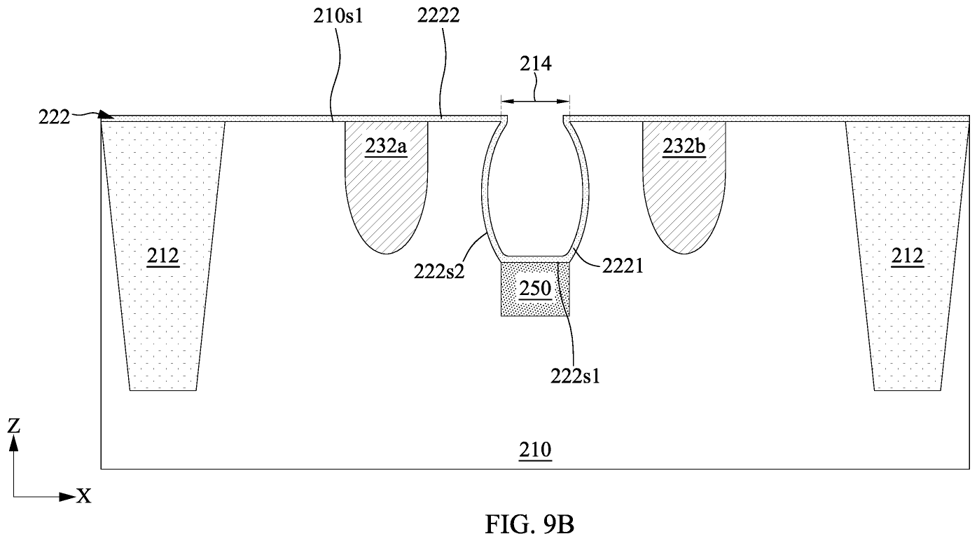

FIG. 9A and FIG. 9B illustrate one or more stages of an exemplary method for manufacturing a semiconductor device structure according to some embodiments of the present disclosure in different perspectives.

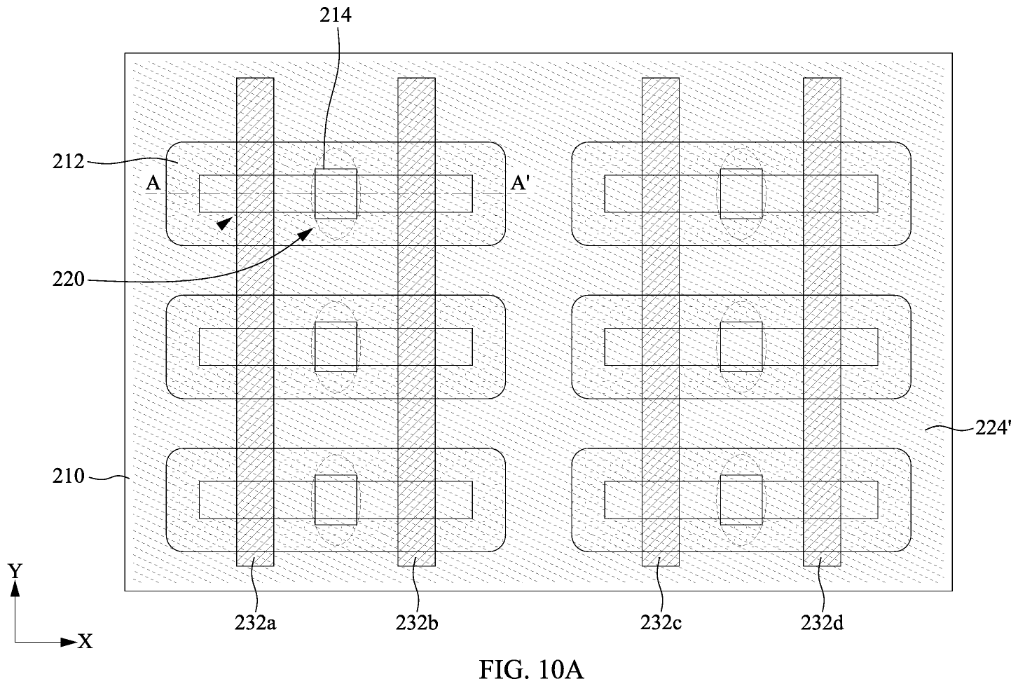

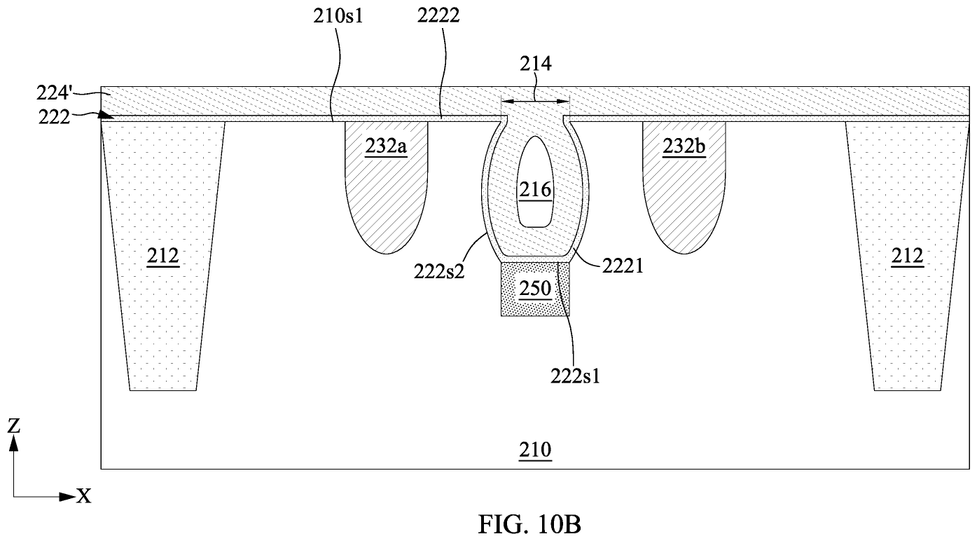

FIG. 10A and FIG. 10B illustrate one or more stages of an exemplary method for manufacturing a semiconductor device structure according to some embodiments of the present disclosure in different perspectives.

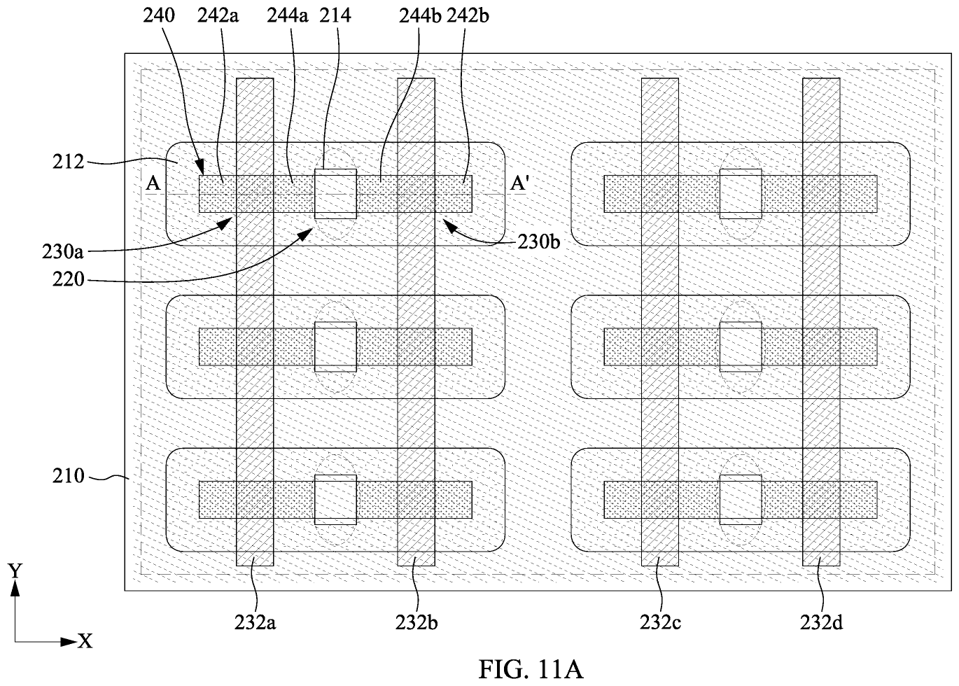

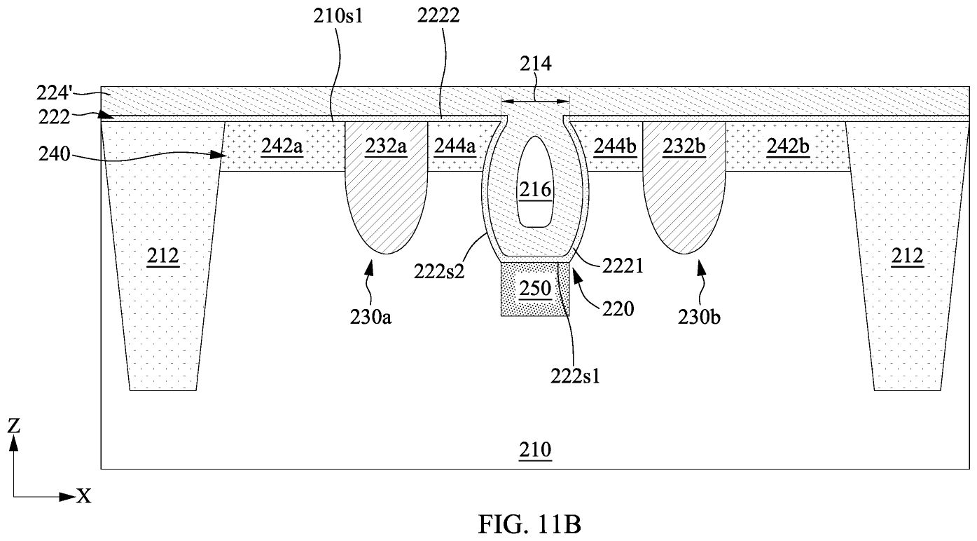

FIG. 11A and FIG. 11B illustrate one or more stages of an exemplary method for manufacturing a semiconductor device structure according to some embodiments of the present disclosure in different perspectives.

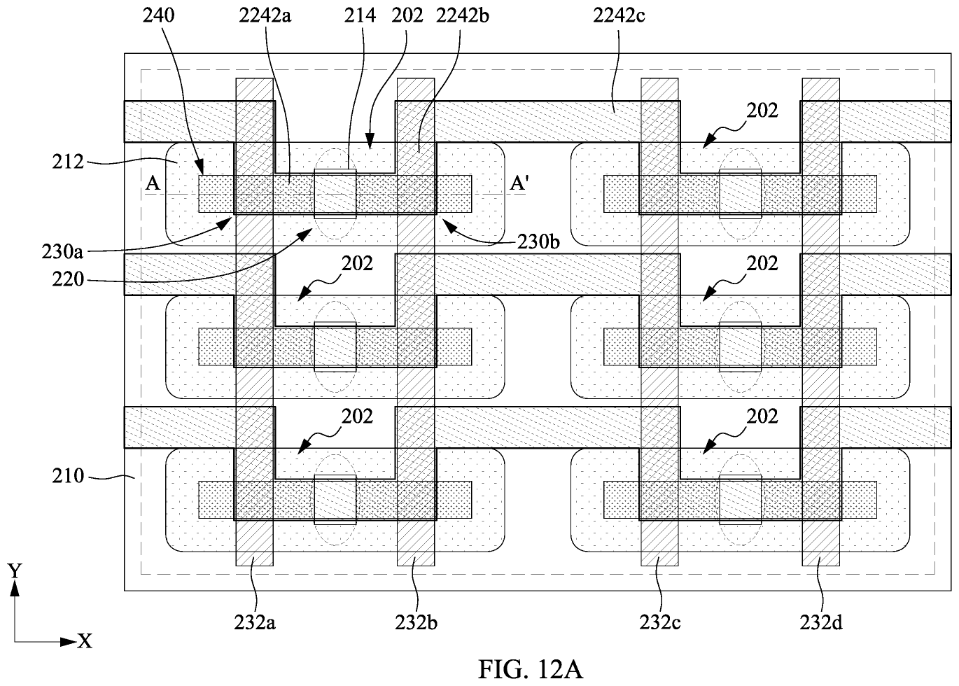

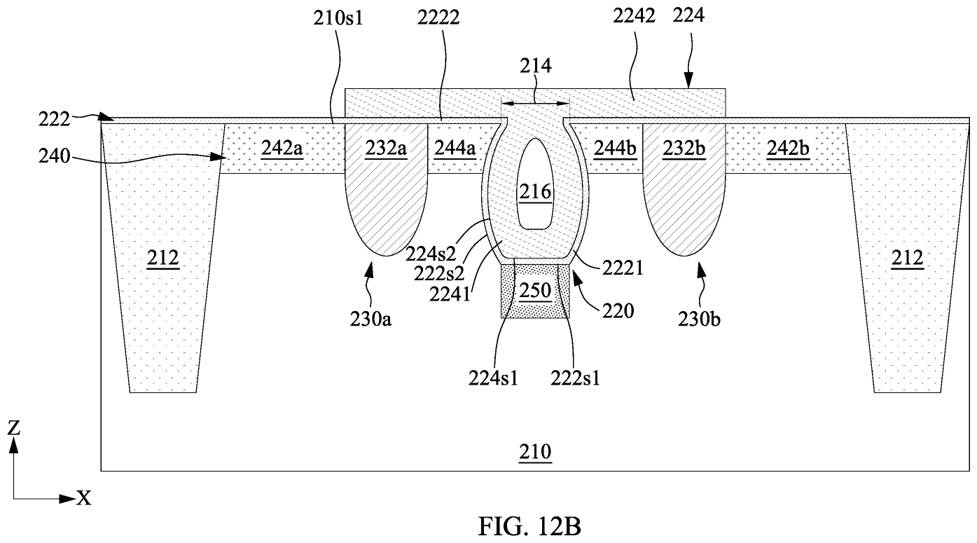

FIG. 12A and FIG. 12B illustrate one or more stages of an exemplary method for manufacturing a semiconductor device structure according to some embodiments of the present disclosure in different perspectives.

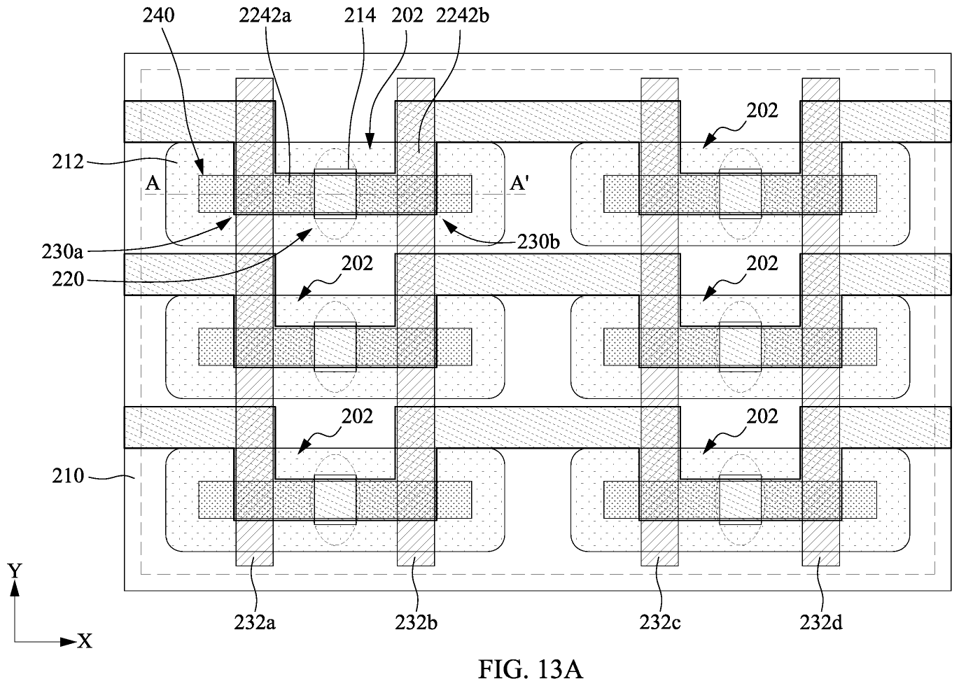

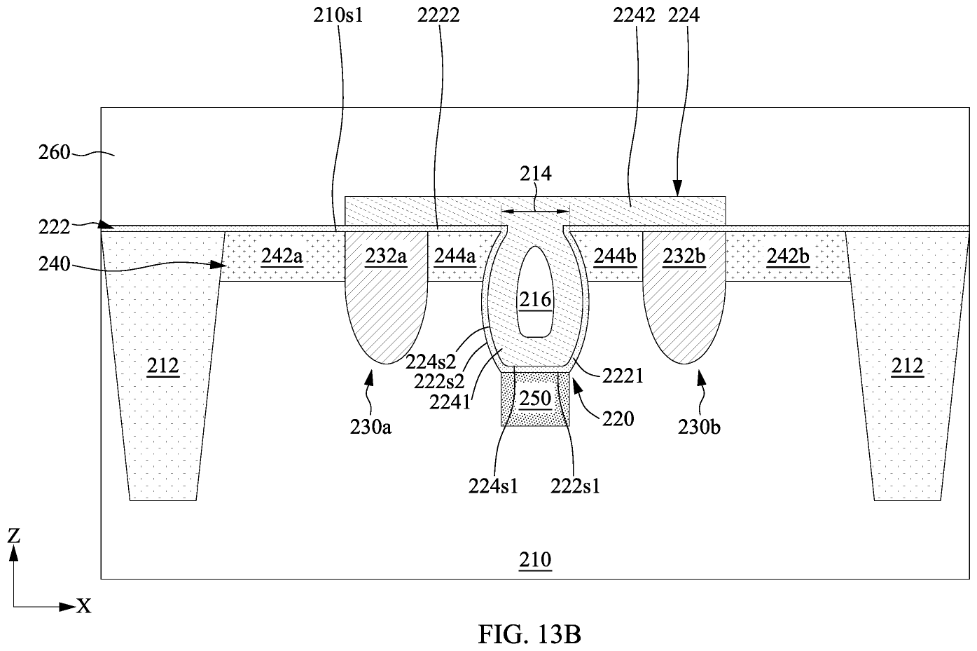

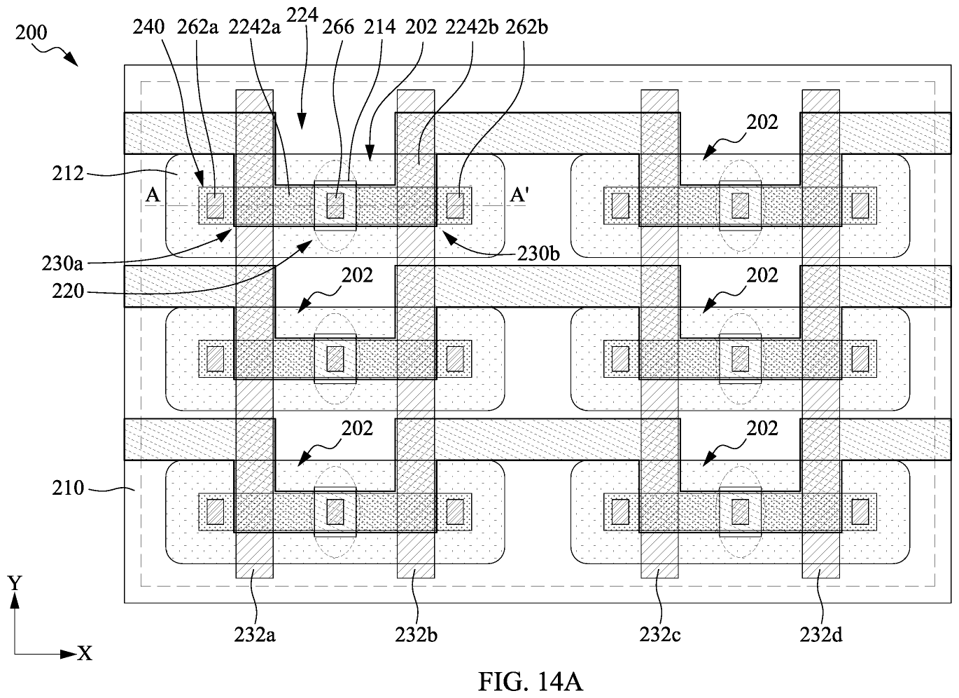

FIG. 13A and FIG. 13B illustrate one or more stages of an exemplary method for manufacturing a semiconductor device structure according to some embodiments of the present disclosure in different perspectives.

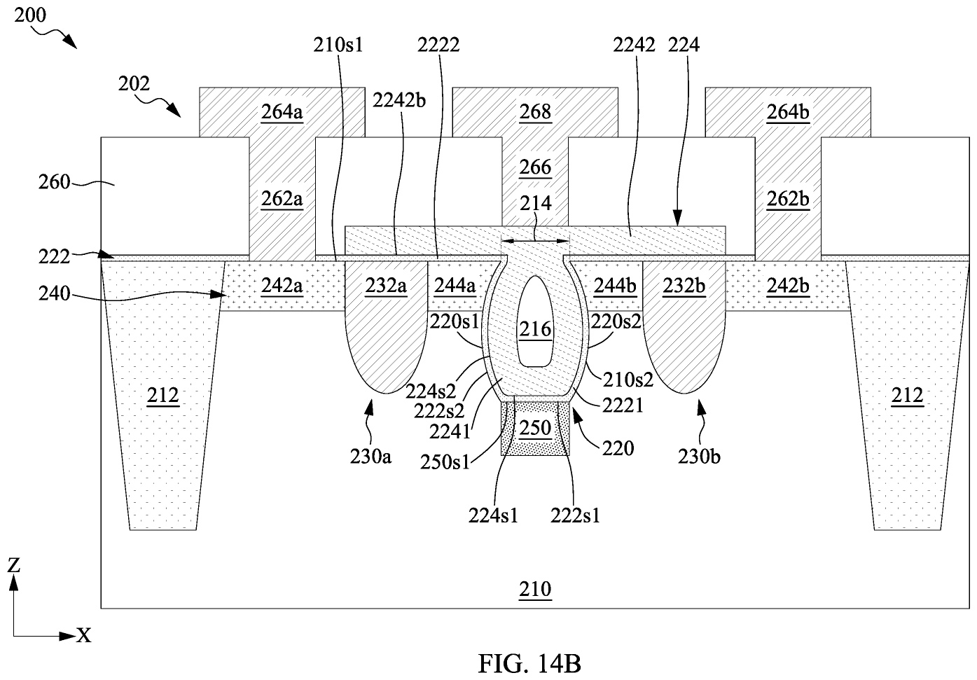

FIG. 14A and FIG. 14B illustrate one or more stages of an exemplary method for manufacturing a semiconductor device structure according to some embodiments of the present disclosure in different perspectives.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that when an element is referred to as being “connected to” or “coupled to” another element, the initial element may be directly connected to, or coupled to, another element, or to other intervening elements.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

It should be noted that the term “about” modifying the quantity of an ingredient, component, or reactant of the present disclosure employed refers to variation in the numerical quantity that may occur, for example, through typical measuring and liquid handling procedures used for making concentrates or solutions. Furthermore, variation may occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. In yet another aspect, the term “about” means within 10, 9, 8, 7, 6, 5, 4, 3, 2, or 1% of the reported numerical value.

FIG. 1 is a schematic diagram of a circuit 100, in accordance with some embodiments of the present disclosure. In some embodiments, the circuit 100 may include a fuse 110, a transistor 120a, and a transistor 120b. In some embodiments, the circuit 100 may be included in a memory device or other suitable devices. The memory device may include, for example, a one-time programming (OTP) memory device, a dynamic random access memory (DRAM) device, a static random access memory (SRAM) device, or other suitable memory devices.

The fuse 110 may include a terminal 111 and a terminal 112. The terminal 111 may be electrically connected to a voltage V1, such as VDDQ. The terminal 112 may be electrically connected to the transistors 120a and 120b.

The transistor 120a may function as a switch to turn on and/or turn off the fuse 110. The transistor 120a may include a terminal 121a, a terminal 122a, and a terminal 123a. The terminal 121a may be electrically connected to a voltage V2. The terminal 122a may be electrically connected to the fuse 110. The terminal 123a may be electrically connected to a node N1, which may be electrically connected to a bit line or a voltage. In some embodiments, the terminal 123a may be electrically connected to ground.

The transistor 120b may function as a switch to turn on and/or turn off the fuse 110. The transistor 120b may include a terminal 121b, a terminal 122b, and a terminal 123b. The terminal 121b may be electrically connected to the voltage V2. The terminal 122b may be electrically connected to the fuse 110. The terminal 123b may be electrically connected to a node N2, which may be electrically connected to a bit line or a voltage. In some embodiments, the terminal 123b may be electrically connected to ground. In some embodiments, the transistors 120a and 120b may be electrically coupled in parallel.

In some embodiments, the circuit 100 may function as a programing unit. In some embodiments, when a relatively large voltage (e.g., 5V or higher) is imposed on the terminal 111, a relatively small voltage (e.g., 2V or lower) is imposed on the terminals 121a and 121b, and the terminals 123a and 123b are electrically connected to ground, the fuse 110 can be blown out. As a result, the resistance state of the circuit 100 is changed.

Referring to FIG. 2A and FIG. 2B, FIG. 2A is a top view of a semiconductor device structure 200, FIG. 2B is a cross-section along line A-A′ of FIG. 2A.

As shown in FIG. 2A, the semiconductor device structure 200 may include a plurality of programming units 202, a substrate 210, and a plurality of isolation structures 212.

In some embodiments, each of the programming units 202 may be configured to enable the operation of the circuit 100 as shown in FIG. 1A. In some embodiments, each of the programming units 202 may be separated by the isolation structure 212. In some embodiments, each of the programming units 202 may include a fuse structure 220, a transistor 230a, and a transistor 230b. In some embodiments, the fuse structure 220 may correspond to the fuse 110 as shown in FIG. 1. In some embodiments, the transistors 230a and 230b may correspond to the transistors 120a and 120b as shown in FIG. 1.

The substrate 210 may define a plurality of openings 214. In some embodiments, the fuse structure 220 may be disposed within the opening 214, which will be described in FIG. 2B.

The semiconductor device structure 200 may include word lines 232a, 232b, 232c, and 232d. Each of the word lines 232a, 232b, 232c, and 232d may extend along the Y direction. The word lines 232a, 232b, 232c, and 232d may function as the terminal 121a (or terminal 121b) as shown in FIG. 1.

The semiconductor device structure 200 may include a plurality of metallization layers 224. Each of the metallization layers 224 may electrically connect two or more program units 202. Each of the metallization layers 224 may electrically connect two or more fuse structures 220. Each of the metallization layers 224 may be configured to impose, transmit, or supply a voltage on a fuse electrode, such as the terminal 111 of the fuse 110 as shown in FIG. 1. In some embodiments, each of the metallization layers 224 may have a plurality of protrusions. In some embodiments, each of the metallization layers 224 may have a portion 2242a, a portion 2242b, and a portion 2242c. The protrusions of the metallization layers 224 may be defined by portions 2242a, 2242b, and 2242c.

In some embodiments, the portion 2242a (or a horizontally extending portion) may extend along the X direction. In some embodiments, the portion 2242a may substantially vertically overlap the active region (e.g., the region including fuse structure and the transistor) of the programming units 202. In some embodiments, the portion 2242a may extend between the word lines 232a and 232b.

In some embodiments, the portion 2242b (or a longitudinally extending portion) may extend along the Y direction. In some embodiments, the portion 2242b may be substantially orthogonal to the portions 2242a and/or 2242c. In some embodiments, the portion 2242b may substantially vertically overlap the word lines 232a, 232b, 232c, and 232d. In some embodiments, the word line 232a may be parallel to the portion 2242b of the metallization layer 224. In some embodiments, the word line 232b may be parallel to the portion 2242b of the metallization layer 224.

In some embodiments, the portion 2242c (or a horizontally extending portion) may extend along the X direction. In some embodiments, the portion 2242a may be parallel to the portion 2242c. In some embodiments, the portion 2242c may be vertically free from overlapping the active region of the programming units 202. In some embodiments, the portion 2242c may be misaligned with the portion 2242a.

The semiconductor device structure 200 may include a doped region 240. The doped region 240 may be configured to define source/drain features of the transistors 230a and 230b. The doped region 240 may be configured to define channels between the transistor 230a (or 230b) and the fuse structure 220.

The semiconductor device structure 200 may include a conductive contact 262a, a conductive contact 262b, and a conductive contact 266. The conductive contact 262a may be disposed over the doped region 240 and electrically connected to the transistor 230a. The conductive contact 262b may be disposed over the doped region 240 and electrically connected to the transistor 230b. The conductive contact 266 may be disposed over the metallization layer 224 and electrically connected to the fuse structure 220.

As shown in FIG. 2B, the substrate 210 may be a semiconductor substrate, such as a bulk semiconductor, a semiconductor-on-insulator (SOI) substrate, or the like. The substrate 210 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. In some embodiments, the substrate 210 may have a multilayer structure, or the substrate 210 may include a multilayer compound semiconductor structure. The substrate 210 may have a surface 210s1. The surface 210s1 may also be referred to as an upper surface.

In some embodiments, the substrate 210 may include a well region (not annotated). In some embodiments, the well region may include a first conductive type. In some embodiments, the first conductive type is a p-type. In some embodiments, p-type dopants include boron (B), other group III elements, or any combination thereof. In some embodiments, the first conductive type is an n-type. In some embodiments, n-type dopants include arsenic (As), phosphorus (P), other group V elements, or any combination thereof.

The isolation structure 212 may be embedded in the substrate 210. The isolation structure 212 may include a shallow trench isolation (STI), a local oxidization of silicon (LOCOS) structure, or any other suitable isolation structure. The isolation structure 212 may include a dielectric material, such as silicon oxide, silicon nitride, silicon oxynitride, or a combination thereof.

The substrate 210 may define the opening 214 extending from the surface 210s1 toward a direction far away from the surface 210s1. In some embodiments, the opening 214 may be disposed between the word lines 232a and 232b. The substrate 210 may have a surface 210s2 (or a lateral surface) defining the sidewall of the opening 214. In some embodiments, the opening 214 may have an oval-shaped profile. In some embodiments, the surface 210s2 of the substrate 210 may be protruded toward the word lines 232a and/or 232b.

The semiconductor device structure 200 may include an isolation layer 222. The isolation layer 222 may include a dielectric material, such as silicon oxide, silicon nitride, silicon oxynitride, or a combination thereof. In some embodiments, the isolation layer 222 may include a single layer structure or a multilayered structure that include an interfacial layer and a high-k (dielectric constant greater than 7) dielectric layer. The high-k dielectric layer may include, but is not limited to, metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k dielectric layer may further include dopants such as, for example, lanthanum and aluminum. In some embodiments, the isolation layer 222 may include a fuse medium 2221 and an upper layer 2222.

In some embodiments, the fuse medium 2221 may be disposed within the opening 214. In some embodiments, the fuse medium 2221 is adapted to change from a first conductive state to a second conductive state after a current exceeding a threshold level flows through the fuse medium 2221. For example, the resistance of the fuse medium 2221 may be changed after a current exceeding a threshold level flows through the fuse medium 2221. Thus, the resistance of the fuse structure 220 may be changed after a current exceeding a threshold level flows through the fuse structure 220. In some embodiments, the fuse medium 2221 has a breakdown after a current exceeding the threshold level flows through the fuse medium 2221.

The fuse medium 2221 may be embedded in the substrate 210. In some embodiments, the fuse medium 2221 may include a surface 222s1 and a surface 222s2. In some embodiments, the surface 222s1 (or a lower surface) may be a substantially flat surface. In some embodiments, the surface 222s1 of the fuse medium 2221 may be substantially parallel to the surface 210s1 of the substrate 210. The surface 222s2 (or a lateral surface) may extend between the surface 210s1 of the substrate 210 and the surface 222s1 of the fuse medium 2221. In some embodiments, the surface 222s2 may include a curved surface. In some embodiments, the surface 222s2 may be protruded toward the word lines 232a and/or 232b.

The upper layer 2222 may be connected to the fuse medium 2221. The upper layer 2222 may be disposed over the surface 210s1 of the substrate 210. In some embodiments, the fuse medium 2221 and the upper layer 2222 may be a monolithic structure.

The semiconductor device structure 200 may include a metallization layer 224. The metallization layer 224 may include a conductive material, such as tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the metallization layer 224 may include a fuse electrode 2241 and a top plate portion 2242.

In some embodiments, the fuse electrode 2241 may be disposed within the opening 214. In some embodiments, the fuse electrode 2241 may function as the terminal 111 of the fuse 110 as shown in FIG. 1. In some embodiments, the fuse electrode 2241 may be disposed on the fuse medium 2221 of the isolation layer 222. The fuse electrode 2241 may be embedded in the substrate 210. In some embodiments, the fuse electrode 2241 may include a surface 224s1 and a surface 224s2. In some embodiments, the surface 224s1 (or a lower surface) may be a substantially flat surface. In some embodiments, the surface 224s1 of the fuse electrode 2241 may be substantially parallel to the surface 210s1 of the substrate 210. The surface 224s2 (or a lateral surface) may extend between the surface 210s1 of the substrate 210 and the surface 224s1 of the fuse electrode 2241. In some embodiments, the surface 224s2 may include a curved surface. In some embodiments, the surface 224s2 may be protruded toward the word lines 232a and/or 232b. In some embodiments, the surface 224s2 of the fuse electrode 224 may vertically overlap the surface 222s2 of the fuse medium 222. In some embodiments, the fuse electrode 2241 may be replaced by a semiconductor material, such as polysilicon, silicon-germanium, and/or other suitable materials.

The top plate portion 2242 may be connected to the fuse electrode 2241. The top plate portion 2242 may be disposed over the surface 210s1 of the substrate 210. The top plate portion 2242 may be disposed over the upper layer 2222 of the isolation layer 222. In some embodiments, the fuse electrode 2241 and the top plate portion 2242 may be a monolithic structure. In some embodiments, the top plate portion 2242 may include the portions 2242a, 2242b, and 2242c as shown in FIG. 2A. In some embodiments, the top plate portion 2242 of the metallization layer 224 may vertically overlap the word line 232a. In some embodiments, the top plate portion 2242 of the metallization layer 224 may vertically overlap the word line 232b. In some embodiments, the top plate portion 2242 of the metallization layer 224 may extend between the word lines 232a and 232b.

In some embodiments, the top plate portion 2242 of the metallization layer 224 may define an air gap 216. In some embodiments, the air gap 216 may be disposed between the transistors 230a and 230b. In some embodiments, the air gap 216 may be disposed between the word lines 232a and 232b. In some embodiments, the air gap 216 may be surrounded by the fuse electrode 2241 of the metallization layer 224. In some embodiments, the air gap 216 may have an oval-shaped profile. The air gap 216 may have a dielectric constant about 1, which thereby improves leakage of the programing unit 202.

In some embodiments, the word line 232a may be disposed at a side 220s1 of the fuse structure 220. In some embodiments, the word line 232a may be embedded within the substrate 210. In some embodiments, the word line 232a may be recessed from the surface 210s1 of the substrate 210. The word line 232a may include conductive materials, such as tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. In some embodiments, the word line 232a may include a semiconductor material, such as polysilicon or other suitable semiconductor materials.

In some embodiments, the word line 232b may be disposed at a side 220s2, opposite to the side 220s1, of the fuse structure 220. In some embodiments, the word line 232b may be embedded within the substrate 210. In some embodiments, the word line 232a may be recessed from the surface 210s1 of the substrate 210. In some embodiments, the word line 232b may be spaced apart from the word line 232a by the fuse structure 220. In some embodiments, the material of the word line 232b may the same as or similar to that of the word line 232a.

In some embodiments, the doped region 240 may be disposed within the substrate 210. The doped region 240 may be adjacent to the surface 210s2 of the substrate 210. In some embodiments, the doped region 240 may have a second conductive type different from the first conductive type. The doped region 240 may surround the word line 232a. The doped region 240 may surround the word line 232b. The doped region 240 may surround the fuse electrode 2241 of the metallization layer 224. The dopant concentration of the doped region 240 may be on the order of 10²⁰ dopant ions/cm³. In some embodiments, the doped region 240 may include doped regions 242a, 242b, 244a, and 244b.

The doped region 242a may be disposed between the isolation structure 212 and the word line 232a. In some embodiments, the doped region 242a may function as a source/drain feature of the transistor 230a.

The doped region 242b may be disposed between the isolation structure 212 and the word line 232b. In some embodiments, the doped region 242b may function as a source/drain feature of the transistor 230b.

The doped region 244a may be disposed between the word line 232a and the fuse structure 220. The doped region 244a may be disposed between the word line 232a and the fuse electrode 2241 of the metallization layer 224. In some embodiments, the doped region 244a may function as a source/drain feature of the transistor 230a. The doped region 244a may function as a channel to transmit carriers or accumulate carriers, which thereby facilitate blowing the fuse structure 220.

The doped region 244b may be disposed between the word line 232b and the fuse structure 220. The doped region 244b may be disposed between the word line 232b and the fuse electrode 2241 of the metallization layer 224. In some embodiments, the doped region 244b may function as a source/drain feature of the transistor 230b. The doped region 244b may function as a channel to transmit carriers or accumulate carriers, which thereby facilitate blowing the fuse structure 220.

In some embodiments, a distance D1 between the word line 232a and the fuse electrode 2241 of the metallization layer 224 may vary along a direction far away from the surface 210s1 of the substrate 210. For example, the word line 232a and the fuse electrode 2241 of the metallization layer 224 may have a smaller distance at the middle, which is between the sidewall of the word line 232a and the surface 224s1, of the surface 224s2; the word line 232a and the fuse electrode 2241 of the metallization layer 224 may have a greater distance adjacent to the surface 210s1 of the substrate 210. In some embodiments, a depth D2 (or a length) of the doped region 240 may be configured to control the location of isolation layer 222 to be blown.

The semiconductor device structure 200 may include a block layer 250 (or an etching stop layer). In some embodiments, the block layer 250 may be embedded in the substrate 210. In some embodiments, the block layer 250 may be disposed under the fuse structure 220. In some embodiments, the block layer 250 may be disposed under the fuse medium 2221. In some embodiments, the block layer 250 may be disposed under the fuse electrode 2241. In some embodiments, the block layer 250 may be in contact with the isolation layer 222. In some embodiments, the material of the block layer 250 may be different from that of the isolation layer 222. The block layer 250 may include a dielectric material, such as silicon nitride, silicon oxide, silicon oxynitride, or a combination thereof. In some embodiments, the block layer 250 may have a surface 250s1 (or an upper surface). The surface 250s1 of the block layer 250 may be a substantially flat surface. In some embodiments, the surface 250s1 of the block layer 250 may be substantially parallel to the surface 210s1 of the substrate 210.

The semiconductor device structure 200 may include a dielectric structure 260. The dielectric structure 260 may be disposed over the surface 210s1 of the substrate 210. In some embodiments, the dielectric structure 260 may cover the metallization layer 224. The dielectric structure 260 may include silicon nitride, silicon oxide, silicon oxynitride, flowable oxide, tonen silazen, undoped silica glass, borosilica glass, phosphosilica glass, borophosphosilica glass, plasma-enhanced tetraethyl orthosilicate, fluoride silicate glass, carbon-doped silicon oxide, or a combination thereof.

The conductive contact 262a may be disposed over the doped region 242a. The conductive contact 262a may be electrically connected to the transistor 230a. The conductive contact 262a may penetrate the dielectric structure 260. The conductive contact 262a may include tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

The conductive contact 262b may be disposed over the doped region 242b. The conductive contact 262b may be electrically connected to the transistor 230b. The conductive contact 262b may penetrate the dielectric structure 260. The conductive contact 262b may include tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

The conductive contact 266 may be disposed over the metallization layer 224. The conductive contact 266 may be electrically connected to the fuse structure 220. The conductive contact 266 may penetrate the dielectric structure 260. The conductive contact 266 may include tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof.

The semiconductor device structure 200 may include a conductive layer 264a, a conductive layer 264b, and a conductive layer 268. The conductive layer 264a may be disposed over the dielectric structure 260. The conductive layer 264a may be electrically connected to the conductive contact 262a.

The conductive layer 264b may be disposed over the dielectric structure 260. The conductive layer 264b may be electrically connected to the conductive contact 262b. Although not shown, the conductive layer 264a may be electrically connected to the conductive layer 264b by traces at higher metallization layer (or by traces at the level the same as that of the conductive layer 264a) so that the word lines 232a and 232b may have the same potential.

The conductive layer 268 may be disposed over the conductive contact 266. The conductive layer 268 may be electrically connected to the conductive contact 266.

In this embodiment, the word lines 232a and 232b are electrically coupled with the fuse structure 220. Further, the word lines 232a and 232b are electrically coupled in parallel. As a result, a relatively large driving current can be generated. The metallization layer 224 has the surface 224s2 protruded toward the word lines 232a and 232b. Therefore, the distance between the fuse structure 220 and the transistor 230a (or transistor 230b) can be reduced. Accordingly, the performance of the semiconductor device structure 200 can be enhanced.

FIG. 3 is a flowchart illustrating a method 300 of manufacturing a semiconductor device structure, in accordance with some embodiments of the present disclosure. More specifically, the method 300 may be configured to produce a programing unit including a fuse structure and two transistors configure to switch the fuse structure.

The method 300 begins with operation 301 in which a substrate may be provided.

The method 300 continues with operation 302 in which a first word line and a second word line may be formed within the substrate.

The method 300 continues with operation 303 in which an opening may be formed within the substrate and between the first word line and the second word line.

The method 300 continues with operation 304 in which a block layer may be formed at the bottom of the opening.

The method 300 continues with operation 305 in which the opening may be enlarged by performing a treatment (e.g., a hydrogen annealing technique). As a result, the opening may have an extending portion protruded toward the first word line and the second word line. That is, the sidewall defining the opening may have a curved surface protruded toward the first word line and the second word line.

The method 300 continues with operation 306 in which an isolation layer and a metallization layer may be formed. As a result, a fuse medium and a fuse electrode may be formed within the opening of the substrate. An air gap may be formed and surrounded by the fuse electrode.

The method 300 continues with operation 307 in which a doped region may be formed within the substrate. As a result, a source/drain feature of the transistor may be defined. Further, a channel between the transistor and the fuse structure may be defined. In this embodiment, a blanket implantation technique may be performed to form the doped region.

The method 300 continues with operation 308 in which a top plate portion of the metallization layer may be patterned. As a result, the top plate portion of the metallization layer may have a first portion, a second portion, and a third portion. The first portion may extend horizontally and overlap the fuse structure as well as the transistors. The first portion may vertically overlap the first word line and the second word line. The second portion may extend longitudinally. The second portion may extend along a direction substantially parallel to an extending direction of the first word line and the second word line. The third portion may be parallel to and misaligned with the first portion.

The method 300 continues with operation 309 in which a first conductive contact and a second conductive contact may be formed over the source/drain feature of the transistors. The first conductive contact may be electrically connected to the second conductive contact.

The method 300 is merely an example, and is not intended to limit the present disclosure beyond what is explicitly recited in the claims. Additional operations can be provided before, during, or after each operation of the method 300, and some operations described can be replaced, eliminated, or reordered for additional embodiments of the method. In some embodiments, the method 300 can include further operations not depicted in FIG. 3. In some embodiments, the method 300 can include one or more operations depicted in FIG. 3.

FIG. 4A to FIG. 14A and FIG. 4B to FIG. 14B illustrate stages of an exemplary method for manufacturing a semiconductor device structure according to some embodiments of the present disclosure in different perspectives. FIG. 4A to FIG. 14A are top views. FIG. 4B to FIG. 14B are cross-sectional views along line A-A′ of FIG. 4A to FIG. 14A, respectively.

Referring to FIG. 4A and FIG. 4B, a substrate 210 may be provided. Isolation structure 212 may be formed within the substrate 210. The isolation structures 212 may be configured to define a region in which programing units, including a fuse structure and transistors are located. Word lines 232a, 232b, 232c, and 232d may be formed within the substrate 210. In some embodiments, trenches (not shown) may be formed and recessed from the surface 210s1 of the substrate 210, and a conductive material or a semiconductor material may fill the trenches to form the word lines 232a, 232b, 232c, and 232d.

Referring to FIG. 5A and FIG. 5B, a mask 272 may be formed over the surface 210s1 of the substrate 210. The mask 272 may include a photosensitive material, such as a photoresist or other suitable materials. The mask 272 may be configured to define opening 214 of the substrate 210. The opening 214 may be formed by a patterning process. The patterning process may include a lithography process, an etching process and other suitable processes. The photolithography process may include photoresist coating (e.g., spin-on coating), soft baking, mask aligning, exposure, post-exposure baking, developing the photoresist, rinsing and drying (e.g., hard baking). The etching process may include, for example, a dry etching process or a wet etching process.

Referring to FIG. 6A and FIG. 6B, a dielectric layer 252 may be formed. The dielectric layer 252 may be formed over the mask 272. The dielectric layer 252 may be formed over the substrate 210. The dielectric layer 252 may fill the opening 214. The dielectric layer 252 may be formed by, for example, chemical vapor deposition (CVD), low-pressure chemical vapor deposition (LPCVD), plasma-enhanced CVD (PECVD), atomic layer deposition (ALD), physical vapor deposition (PVD), or other suitable processes. The dielectric layer 252 may include a dielectric material, such as silicon nitride, silicon oxide, silicon oxynitride, or a combination thereof.

Referring to FIG. 7A and FIG. 7B, a portion of the dielectric layer 252 may be removed to define a block layer 250 on the bottom of the opening 214 of the substrate 210.

Referring to FIG. 8A and FIG. 8B, a treatment P1 may be performed. The opening 214 may be enlarged. The opening 214 may include an extending portion 214e under the surface 210s2 of the substrate 210. The extending portion 214e may be protruded toward the word lines 232a and 232b. In some embodiments, the treatment P1 may include an annealing technique (or an etching technique). In some embodiments, the treatment P1 may include a hydrogen (H₂) annealing technique. In some embodiments, the gas 282 of the anneal technique may include hydrogen or other suitable gases. The block layer 250 may be configured to prevent the depth of the opening 214 being enlarged. The block layer 250 may block the gas 282.

Referring to FIG. 9A and FIG. 9B, the mask 272 may be removed. An isolation layer 222 may be formed. The isolation layer 222 may include a fuse medium 2221 formed within the opening 214 and an upper layer 2222 formed over the surface 210s1 of the substrate 210. The fuse medium 2221 may be formed over the block layer 250. The fuse medium 2221 may have a surface 222s2 protruded toward the word lines 232a and 232b. The mask 272 may be formed by ALD, CVD, PVD, LPCVD, PECVD, or other suitable processes.

Referring to FIG. 10A and FIG. 10B, a conductive layer 224′ may be formed. The conductive layer 224′ may be formed over the isolation layer 222. The conductive layer 224′ may be formed within the opening 214 and define an air gap 216 within the substrate 210. The conductive layer 224′ may be formed by PVD, CVD, ALD, LPCVD, PECVD, or other suitable processes.

Referring to FIG. 11A and FIG. 11B, a doped region 240 may be formed. In some embodiments, a blanket implantation technique may be performed to form the doped region 240. That is, no reticle(s) or mask(s) are required to form the doped region 240. Therefore, the cost may be reduced. The doped region 240 may include a doped region 242a, a doped region 242b, a doped region 244a, and a doped region 244b. The source/drain features of the transistors 230a and 230b may be defined. The channel between the transistor 230a (or transistor 230b) and the fuse structure 220 may be defined.

Referring to FIG. 12A and FIG. 12B, the conductive layer 224′ may be patterned to define the metallization layer 224. The metallization layer 224 may include a fuse electrode 2241 formed within the opening 214 and a top plate portion 2242 formed over the surface 210s1 of the substrate 210. The fuse electrode 2241 may have a surface 224s2 protruded toward the word lines 232a and 232b. The metallization layer 224 may include a portion 2242a extending between the word lines 232a and 232b. The metallization layer 224 may include a portion 2242b parallel to the word lines 232a and 232b. The metallization layer 224 may include a portion 2242c parallel to the portion 2242a.

Referring to FIG. 13A and FIG. 13B, a dielectric structure 260 may be formed to cover the substrate 210 and the metallization layer 224. The dielectric structure 260 may be formed by CVD, PVD, ALD, LPCVD, PECVD, or other suitable processes.

Referring to FIG. 14A and FIG. 14B, a conductive contact 262a, a conductive contact 262b, a conductive contact 266, a conductive layer 264a, a conductive layer 264b, and a conductive layer 268 may be formed. As a result, a semiconductor device structure, such as the semiconductor device structure 200 as shown in FIG. 2A and FIG. 2B, may be produced.

One aspect of the present disclosure provides a semiconductor device structure. The semiconductor device structure includes a substrate, a fuse structure, and a first word line. The fuse structure includes a fuse electrode disposed within the substrate. The first word line is electrically coupled to the fuse structure. The first word line is disposed within the substrate and spaced apart from the fuse electrode of the fuse structure. The fuse electrode has a lateral surface protruding toward the first word line.

Another aspect of the present disclosure provides a semiconductor device structure. The semiconductor device structure includes a substrate, a fuse structure, and a first word line. The fuse structure includes a fuse electrode disposed within the substrate. The first word line is electrically coupled to the fuse structure. A distance between the fuse electrode of the fuse structure and the first word line varies along a direction far away from the substrate.

Another aspect of the present disclosure provides a method for manufacturing a semiconductor device structure. The method includes: providing a substrate; forming a first word line and a second word line within the substrate; forming an opening extending from an upper surface of the substrate and between the first word line and the second word line; and forming an insulation layer within the opening; and forming a metallization layer over the insulation layer to define a fuse structure.

The embodiments of the present disclosure provide a semiconductor device structure. The semiconductor device structure includes a substrate, a fuse structure, a first word line, and a second word line. The first word line is electrically coupled with the fuse structure. Further, the first word line and the second word line are electrically coupled in parallel. As a result, a relatively large driving current can be generated. The electrode of the fuse structure has a lateral surface protruded toward the first word line and the second word line. The semiconductor device structure can have a relatively small resistance between the fuse structure and the first word line (or the second word line). Accordingly, the fuse structure can be blown out with a smaller voltage. Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

It should be noted that, in the description of the present disclosure, an x-y-z coordinate system is assumed where x and y refer to dimensions within the plane parallel to the major surface of the structure and z refers a dimension perpendicular to the plane, two features are topographically aligned or a feature is topographically above another feature when those features have substantially the same x, y coordinates.

It should be noted that, in the description of the present disclosure, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

It should be noted that, in the description of the present disclosure, some elements (e.g., substrate and first dielectric layer) in the schematic top-view diagrams may be omitted for clarity.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device structure, comprising:
a substrate;
a fuse structure comprising a fuse electrode disposed within the substrate; and
a first word line electrically coupled to the fuse structure, wherein the first word line is disposed within the substrate and spaced apart from the fuse electrode of the fuse structure,
wherein the fuse electrode has a lateral surface protruding toward the first word line.

2. The semiconductor device structure of claim 1, wherein the fuse structure comprises a fuse medium separating the fuse electrode from the substrate, and the fuse medium has a lateral surface protruding toward the first word line.

3. The semiconductor device structure of claim 1, further comprising:
an air gap surrounded by the fuse electrode.

4. The semiconductor device structure of claim 1, further comprising:
a second word line electrically connected to the fuse structure.

5. The semiconductor device structure of claim 4, wherein the first word line is electrically connected to the second word line in parallel.

6. The semiconductor device structure of claim 4, further comprising:
a metallization layer disposed on the substrate and electrically connected to the fuse electrode of the fuse structure, wherein the metallization layer vertically overlaps the first word line.

7. The semiconductor device structure of claim 6, wherein the metallization layer vertically overlaps the second word line.

8. The semiconductor device structure of claim 6, wherein the metallization layer has a first portion extending along a first direction and a second portion extending along a second direction different from the first direction.

9. The semiconductor device structure of claim 1, further comprising:
a block layer disposed under the fuse electrode of the fuse structure.

10. The semiconductor device structure of claim 1, wherein a lower surface of the fuse electrode is substantially parallel to an upper surface of the substrate.

11. The semiconductor device structure of claim 1, further comprising:
a doped region disposed within the substrate and in contact with the lateral surface of the first word line.

12. A semiconductor device structure, comprising:
a substrate;
a fuse structure comprising a fuse electrode disposed within the substrate; and
a first word line electrically coupled to the fuse structure,
wherein a horizontal distance between the fuse electrode of the fuse structure and the first word line changes along a direction far away from the substrate.

13. The semiconductor device structure of claim 12, further comprising:
a second word line electrically connected to the fuse structure.

14. The semiconductor device structure of claim 13, wherein the first word line is electrically connected to the second word line in parallel.

15. The semiconductor device structure of claim 13, further comprising:
an air gap disposed between the first word line and the second word line.

16. The semiconductor device structure of claim 13, further comprising:
a metallization layer disposed on the substrate and electrically connected to the fuse electrode of the fuse structure, wherein the metallization layer vertically overlaps the first word line.

17. The semiconductor device structure of claim 16, wherein the metallization layer has a first portion extending between the first word line and second word line and a second portion substantially orthogonal to the first portion.

18. The semiconductor device structure of claim 16, wherein the metallization layer vertically overlaps the second word line.

19. The semiconductor device structure of claim 16, wherein the fuse electrode has a lateral surface protruded toward the first word line.

20. The semiconductor device structure of claim 19, wherein the fuse electrode has a lower surface substantially parallel to an upper surface of the substrate.
